(19) United States
(12) Patent Application Publication
(10) Pub. No.: US 2014/0042454 A1
(43) Pub. Date: Feb. 13, 2014

(54) SEMICONDUCTOR LIGHT EMTTING DEVICE

(71) Applicant: SAMSUNG ELECTRONICS CO., LTD., Suwon-si (KR)

(72) Inventors: Jin Sub LEE, Suwon-si (KR); Jung Sub KIM, Hwaseong-si (KR); Cheol Soo SONE, Seoul (KR)

(73) Assignee: SAMSUNG ELECTRONICS CO., LTD.

(21) Appl. No.: 13/944,669

(22) Filed: Jul. 17, 2013

(30) Foreign Application Priority Data
Aug. 13, 2012 (KR) 10-2012-0088200

(51) Int. Cl. H01L 33/32

(52) U.S. Cl. CPC H01L 33/325
USPC 257/76

(57) ABSTRACT

A semiconductor light emitting device includes a substrate, a buffer layer disposed on the substrate, the buffer layer comprising aluminum nitride, a composition grading layer disposed on the buffer layer, the composition grading layer comprising first aluminum nitride and second aluminum nitride, a capping layer disposed on the composition grading layer, and a cladding layer disposed on the capping layer. A composition of the first aluminum nitride and a composition of the second aluminum nitride change gradually in an alternating manner.

### CROSS-REFERENCE TO RELATED APPLICATION(S)

This application claims benefit of priority to Korean Patent Application No. 10-2012-0088200, filed on Aug. 13, 2012, in the Korean Intellectual Property Office, the entire contents of which are hereby incorporated by reference.

### TECHNICAL FIELD

Exemplary embodiments of the present inventive concept relate to a semiconductor light emitting device, and more particularly, to a semiconductor light emitting device that may reduce a crystal defect caused by differences in a thermal expansion coefficient and a lattice constant between a semiconductor thin film and a substrate to improve crystallinity of the semiconductor thin film.

### BACKGROUND

Having excellent properties in terms of thermal stability, electrical conductivity, and thermal conductivity and a wide band gap, aluminum nitride (AlN) is gaining attention as a next generation material. With an increased interest in AlN, attempts have been made to utilize AlN in various fields of industry including an ultraviolet light emitting device (UV-LED).

Accordingly, a demand exists for high electrical properties of an n-aluminum gallium nitride (AlGaN) cladding layer used for electron injection in fabricating a high-output deep ultraviolet (DUV) device. However, as a mole fraction of aluminum (Al) increases during deep UV epi growth, an ionization energy of silicon (Si) increases, thereby reducing doping efficiency. A large lattice mismatch between a cladding layer and a buffer layer causes threading dislocation and various defects, resulting in reduced sheet resistivity (Rs). Also, a strong parasitic reaction of a trimethylaluminum (TMA) lightly-doped-drain (LDD) structure restrains growth control, which fails to achieve uniformity. To overcome these issues, improved properties are needed.

Various growth schemes are used to reduce a lattice mismatch between an n-cladding layer and a layer below the n-cladding layer that may occur during growth of the n-cladding layer in the fabrication of a DUV device or a blue LED. Among them, a superlattice growth scheme relieves strains by stacking layers having different compositions in an alternating manner. However, difficult problems exist in improving crystallinity and resolving non-uniformity across a wafer during DUV-based growth.

### SUMMARY

An aspect of the present inventive concept relates to a semiconductor light emitting device that may reduce a threading dislocation and various defects caused by a lattice mismatch between layers when stacking and may improve uniformity of a semiconductor material on a wafer.

One aspect of the present inventive concept encompasses a semiconductor light emitting device including a substrate, a buffer layer disposed on the substrate, the buffer layer including aluminum nitride, a composition grading layer disposed on the buffer layer, the composition grading layer including first aluminum nitride and second aluminum nitride, a capping layer disposed on the composition grading layer, and a cladding layer disposed on the capping layer. A composition of the first aluminum nitride and a composition of the second aluminum nitride change gradually in an alternating manner.

The composition grading layer may include a first composition grading layer through an n^{th} composition grading layer on the buffer layer.

A concentration of aluminum in first aluminum nitride and second aluminum nitride of the (n−1)th composition grading layer may be greater than or equal to a concentration of aluminum in first aluminum nitride and second aluminum nitride of the n^{th} composition grading layer.

A concentration of gallium in first aluminum nitride and second aluminum nitride of the (n−1)th composition grading layer may be less than or equal to a concentration of gallium in first aluminum nitride and second aluminum nitride of the n^{th} composition grading layer.

A composition of the buffer layer may be equal to a composition of second aluminum nitride of a lowermost layer of the composition grading layer.

A composition of the capping layer may be equal to a composition of first aluminum nitride of a topmost layer of the composition grading layer.

Each of the first aluminum nitride and the second aluminum nitride of the composition grading layer may include aluminum gallium nitride (AlₓGa₁₋ₓN), independently, where 0≦x≦1.

The cladding layer may include AlₓGa₁₋ₓN, where 0.50≦x≦0.60.

Each of the first composition grading layer through the n^{th} composition grading layer may include at least two pairs of layers, independently.

Another aspect of the present inventive concept relates to a semiconductor light emitting device including a substrate, a buffer layer disposed on the substrate, the buffer layer including aluminum nitride, a composition grading layer disposed on the buffer layer, the composition grading layer including first aluminum nitride and second aluminum nitride, a capping layer disposed on the composition grading layer, and a cladding layer disposed on the capping layer. The composition grading layer includes layers in which a gradual compositional change occurs in one of the first aluminum nitride and the second aluminum nitride while no compositional change is made in the other of the first aluminum nitride and the second aluminum nitride.

A composition of the first aluminum nitride and a composition of the second aluminum nitride may change gradually in an alternating manner.

### BRIEF DESCRIPTION OF THE DRAWINGS

The patent or application file contains at least one drawing executed in color. Copies of this patent application publication with color drawing(s) will be provided by the Office upon request and payment of the necessary fee.

The foregoing and other features of the inventive concept will be apparent from more particular description of embodiments of the inventive concept, as illustrated in the accompanying drawings in which like reference characters may refer to the same or similar parts throughout the different views. The drawings are not necessarily to scale, emphasis instead being placed upon illustrating the principles of the embodiments of the inventive concept. In the drawings, the thickness of layers and regions may be exaggerated for clarity.

FIG. 1 is a cross-sectional view illustrating an example of a semiconductor light emitting device according to an embodiment of the present inventive concept.

FIG. 2 is a cross-sectional view illustrating another example of a semiconductor light emitting device including a three-layered composition grading layer according to an embodiment of the present inventive concept.

FIG. 3 is a cross-sectional view illustrating still another example of a semiconductor light emitting device including a five-layered composition grading layer according to an embodiment of the present inventive concept.

FIG. 4 is a cross-sectional view illustrating an elemental composition in an example of the semiconductor light emitting device of FIG. 2.

FIG. 5 is a cross-sectional view illustrating an elemental composition in another example of the semiconductor light emitting device of FIG. 2.

FIG. 6 is a cross-sectional view illustrating an elemental composition in an example of the semiconductor light emitting device of FIG. 3.

FIG. 7A is a photographic image of a surface of a center of a semiconductor light emitting device as a Comparative Example, and 7B is a photographic image of a surface of a to center of a semiconductor light emitting device according to an exemplary embodiment of the present inventive concept.

### DETAILED DESCRIPTION

Examples of the present inventive concept will be described below in more detail with reference to the accompanying drawings. The examples of the present inventive concept may, however, be embodied in different forms and should not be construed as limited to the examples set forth herein. Like reference numerals may refer to like elements throughout the specification.

In the description of embodiments of the present inventive concept, it will be understood that when an element or a layer is referred to as being “on” another element or another layer, it can be directly on the other element or layer, or intervening elements or layers may be present.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

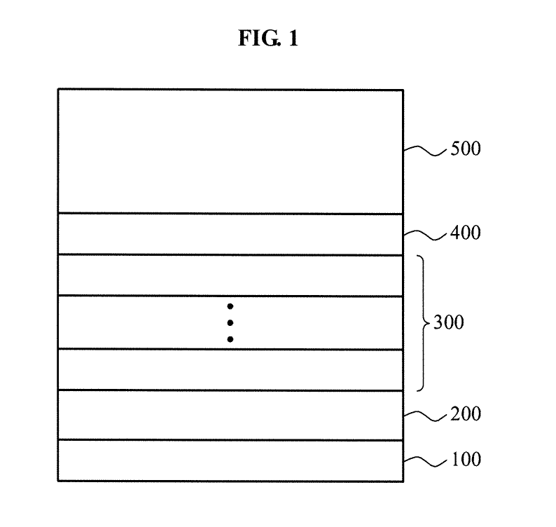

FIG. 1 is a cross-sectional view illustrating an example of a semiconductor light emitting device according to an exemplary embodiment of the present inventive concept.

Referring to FIG. 1, the semiconductor light emitting device may include a substrate 100, a buffer layer 200 formed on the substrate 100, a composition grading layer 300 formed on the buffer layer 200 and including first aluminum nitride and second aluminum nitride, a capping layer 400 formed on the composition grading layer 300, and a cladding layer 500 formed on the capping layer 400.

In the semiconductor light emitting device according to an exemplary embodiment of the present inventive concept, a composition the first aluminum nitride and a composition of the second aluminum nitride change gradually in an alternating manner.

The substrate 100 may include any type of substrate on which a semiconductor layer is allowed to grow. For example, the substrate 100 may be made of a material selected from sapphire, magnesium aluminate (MgAl₂O₄) spinel, gallium nitride (GaN), gallium arsenide (GaAs), silicon carbide (SiC), silicon (Si), zinc oxide (ZnO), zirconium diboride (ZrB₂), gallium phosphide (GaP), diamond, and combinations thereof, however, the present inventive concept is not limited to a specific material. Further, a size or thickness of the substrate 100 is not limited to a specific value. A plane orientation of the substrate 100 is not specially limited, and the substrate 100 may include an off-substrate with an off-angle, or a substrate without an off-angle, called a just substrate.

The aluminum nitride (AlN) buffer layer 200 may be formed on the substrate 100. The buffer layer 200, the composition grading layer 300, the capping layer 400, and the cladding layer 500 of the semiconductor light emitting device may be grown using various techniques, for example, physical deposition and chemical deposition, including metal organic chemical vapor deposition (MOCVD), molecular beam epitaxy (MBE), vapor phase epitaxy (VPE), hydride vapor phase epitaxy (HVPE), metal organic vapor phase epitaxy (MOVPE), low pressure chemical vapor deposition (LPCVD), atomic layer deposition (ALD), and the like, however, the present inventive concept is not limited to a specific technique.

The composition grading layer 300 may be formed on the buffer layer 200 with varying concentrations of Al and Ga.

The composition grading layer 300 may include, but is not limited to, a first composition grading layer through an n^{th} composition grading layer on the buffer layer 200. As an example, the composition grading layer 300 may include a first composition grading layer, a second composition grading layer, a third composition grading layer, a fourth composition grading layer, a fifth composition grading layer, . . . , and an n^{th} composition grading layer in a sequential order, on the buffer layer 200. The capping layer 400 may be formed on the n^{th} composition grading layer.

Each of the first aluminum nitride and the second aluminum nitride of the composition grading layer 300 may include aluminum gallium nitride (AlₓGa₁₋ₓN), independently, where 0≦x≦1, however, the present inventive concept is not limited to a specific composition.

A concentration of aluminum in the first aluminum nitride and the second aluminum nitride of the (n−1)th composition grading layer may be greater than or equal to a concentration of the first aluminum nitride and the second aluminum nitride of the n^{th} composition grading layer, however, the present inventive concept is not limited thereto.

A concentration of gallium in the first aluminum nitride and the second aluminum nitride of the (n−1)th composition grading layer may be less than or equal to a concentration of the first aluminum nitride and the second aluminum nitride of the n^{th} composition grading layer, however, the present inventive concept is not limited thereto.

A composition of the buffer layer 200 may be equal to a composition of second aluminum nitride of a lowermost layer in the composition grading layer 300, however, the present inventive concept is not limited thereto.

As an example, when the composition grading layer 300 is formed of three layers, a composition of the buffer layer 200 and a composition of the second aluminum nitride of the first composition grading layer may be the same material, AlN, in which a concentration of gallium is 0 in a composition represented by AlₓGa₁₋ₓN where 0≦x≦1.

A composition of the capping layer 400 may be equal to a composition of the first aluminum nitride of a topmost layer in the composition grading layer 300, however, the present inventive concept is not limited thereto.

As another example, when the composition grading layer 300 is formed of three layers, a composition of the capping layer 400 and a composition of the first aluminum nitride of the third composition grading layer may be the same material, Al_{0.6}Ga_{0.4}N, in which a concentration of gallium is 0.4 in a composition represented by AlₓGa₁₋ₓN where 0≦x≦1.

The cladding layer 500 may include AlₓGa₁₋ₓN, where 0.50≦x≦0.60, however, the present inventive concept is not limited to a specific composition. For example, the cladding layer 500 may include Al_{0.50}Ga_{0.50}N, Al_{0.53}Ga_{0.47}N, Al_{0.55}Ga_{0.45}N, Al_{0.57}Ga_{0.43}N, or Al_{0.6}Ga_{0.4}N.

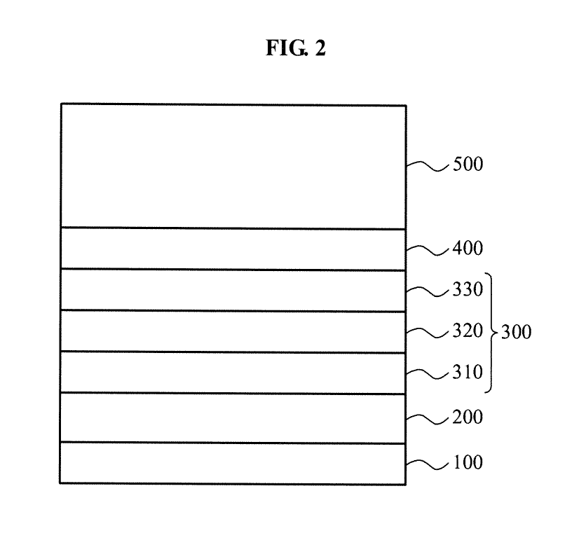

FIG. 2 is a cross-sectional view illustrating another example of a semiconductor light emitting device including a three-layered composition grading layer according to an exemplary embodiment of the present inventive concept.

Referring to FIG. 2, as an example, when the composition grading layer 300 is formed of three layers, the composition grading layer 300 may include a first composition grading layer 310, a second composition grading layer 320, and a third composition grading layer 330.

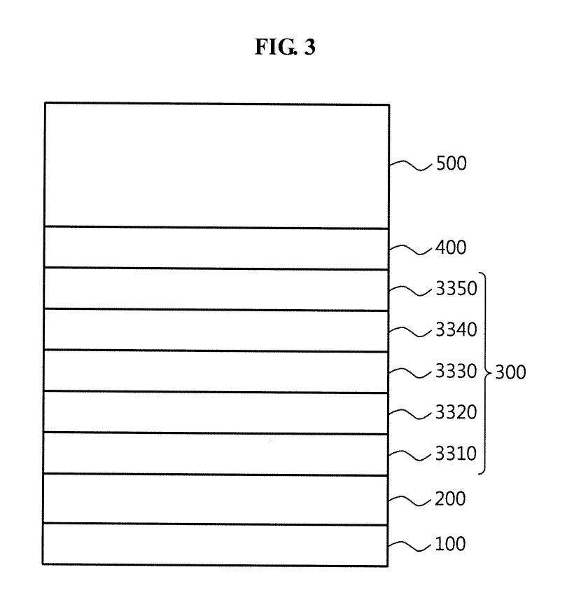

FIG. 3 is a cross-sectional view illustrating an example of a semiconductor light emitting device including a five-layered composition grading layer according to an exemplary embodiment of the present inventive concept.

Referring to FIG. 3, as an example, when the composition grading layer 300 is formed of five layers, the composition grading layer 300 may include a first composition grading layer 3310, a second composition grading layer 3320, a third composition grading layer 3330, a fourth composition grading layer 3340, and a fifth composition grading layer 3350.

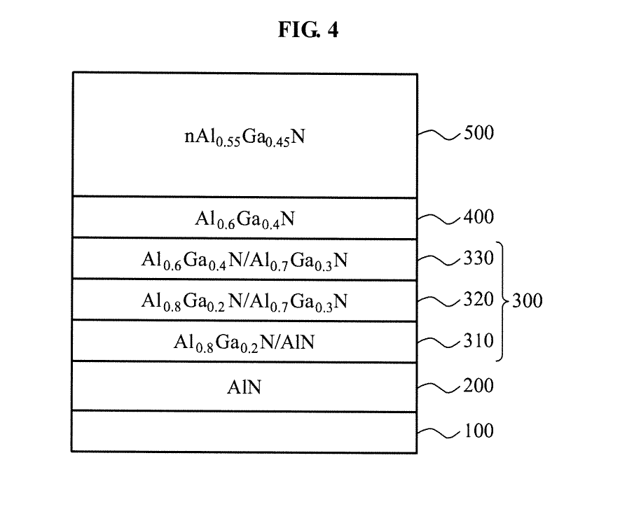

FIG. 4 is a cross-sectional view illustrating an elemental composition in an example of the semiconductor light emitting device of FIG. 2.

Referring to FIG. 4, the first aluminum nitride of the first composition grading layer 310 contacting the buffer layer 200 may include Al_{0.8}Ga_{0.2}N, and the second aluminum nitride of the first composition grading layer 310 may include AlN. The composition of the first aluminum nitride of the first composition grading layer 310 differs from the composition of the buffer layer 200, while the composition of the second aluminum nitride of the first composition grading layer 310 is equal to the composition of the buffer layer 200 such that the effects of compositional changes may be minimized.

The first aluminum nitride of the second composition grading layer 320 may include Al_{0.8}Ga_{0.2}N, and the second aluminum nitride of the second composition grading layer 320 may include Al_{0.7}Ga_{0.3}N. When compared to the first composition grading layer 310, the composition of the first aluminum nitride between the first composition grading layer 310 and the second composition grading layer 320 is unchanged and maintained such that the effects of compositional changes may be minimized, while a change in composition of the second aluminum nitride between the first composition grading layer 310 and the second composition grading layer 320 is made.

The first aluminum nitride of the third composition grading layer 330 may include Al_{0.6}Ga_{0.4}N, and the second aluminum nitride of the third composition grading layer 330 may include Al_{0.7}Ga_{0.3}N. When compared to the second composition grading layer 320, the composition of the second aluminum nitride of the third composition grading layer 330 is equal to the composition of the second aluminum nitride of the second composition grading layer 320 such that the effects of compositional changes may be minimized, while a change in composition of the first aluminum nitride between the second composition grading layer 320 and the third composition grading layer 330 is made.

The change in composition between the first composition grading layer 310, the second composition grading layer 320, and the third composition grading layer 330 may be made in such a way that a change in composition of the second aluminum nitride (between the first composition grading layer 310 and the second composition grading layer 320) and a change in composition of the first aluminum nitride (between the second composition grading layer 320 and the third composition grading layer 330) alternate. Also, the composition grading layer 300 may include layers in which a gradual compositional change occurs in one of the first and second aluminum nitride while no compositional change is made in the other of the first and second aluminum nitride.

The composition of the first aluminum nitride of the third composition grading layer 330 contacting the capping layer 400 may be equal to the composition of the capping layer 400 to minimize the effects of the compositional changes between the composition grading layer 300 and the capping layer 400.

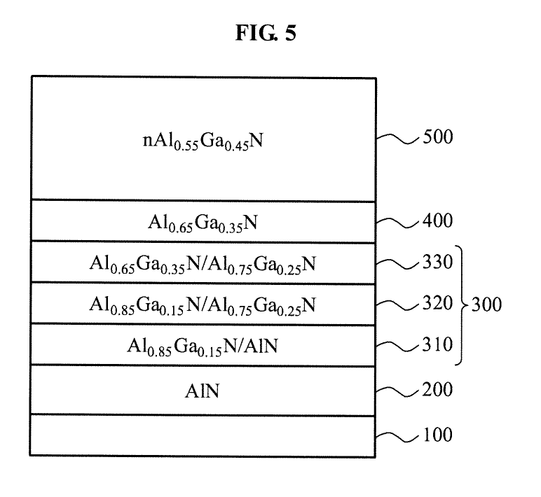

FIG. 5 is a cross-sectional view illustrating an elemental composition in another example of the semiconductor light emitting device of FIG. 2.

The composition of the composition grading layer of FIG. 2 does not have a fixed value. That is, for example, an exemplary composition of the composition grading layer of FIG. 5 may have a different value from an exemplary composition of the composition grading layer of FIG. 4. However, a tendency of compositional changes may be identical such that a change in composition of the first aluminum nitride and a change in composition of the second aluminum nitride alternate.

Referring to FIG. 5, the first aluminum nitride of the first composition grading layer 310 contacting the buffer layer 200 may include Al_{0.85}Ga_{0.15}N, and the second aluminum nitride of the first composition grading layer 310 may include AlN. The composition of the first aluminum nitride of the first composition grading layer 310 differs from the composition of the buffer layer 200, while the composition of the second aluminum nitride of the first composition grading layer 310 is equal to the composition of the buffer layer 200.

The first aluminum nitride of the second composition grading layer 320 may include Al_{0.85}Ga_{0.15}N, and the second aluminum nitride of the second composition grading layer 320 may include Al_{0.75}Ga_{0.25}N. When compared to the first composition grading layer 310, the composition of the first aluminum nitride between the first composition grading layer 310 and the second composition grading layer 320 is unchanged and maintained such that the effects of compositional changes may be minimized, while a change in composition of the second aluminum nitride between the first composition grading layer 310 and the second composition grading layer 320 is made.

The first aluminum nitride of the third composition grading layer 330 may include Al_{0.65}Ga_{0.35}N, and the second aluminum nitride of the third composition grading layer 330 may include Al_{0.75}Ga_{0.25}N. When compared to the second composition grading layer 320, the composition of the second aluminum nitride of the third composition grading layer 330 is equal to the composition of the second aluminum nitride of the second composition grading layer 320, while a change in composition of the first aluminum nitride between the second composition grading layer 320 and the third composition grading layer 330 is made.

After a change in composition of the second aluminum nitride is made between the first composition grading layer 310 and the second composition grading layer 320, a change in composition of the first aluminum nitride may be made between the second composition grading layer 320 and the third composition grading layer 330, on an alternating basis. Also, the composition grading layer 300 may include layers in which a gradual compositional change occurs in one of the first and second aluminum nitride while no compositional change is made in the other of the first and second aluminum nitride.

The composition of the first aluminum nitride of the third composition grading layer 330 contacting the capping layer 400 may be equal to the composition of the capping layer 400 to minimize the effects of compositional changes between the composition grading layer 300 and the capping layer 400.

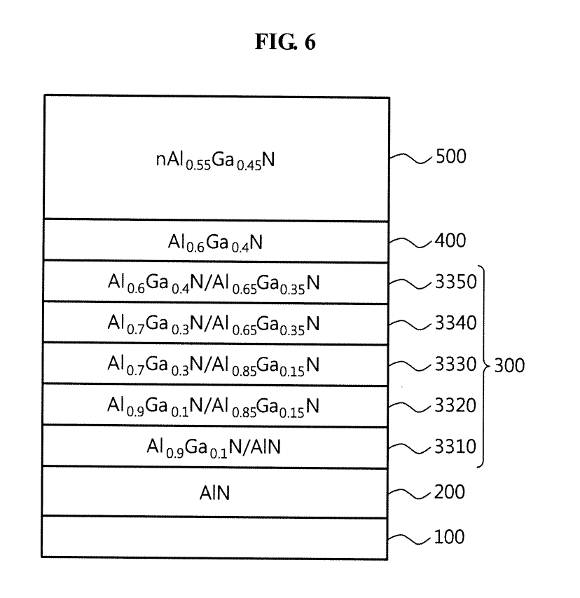

Although FIGS. 2, 4 and 5 show a three-layered composition grading layer, the present inventive concept is not limited to a specific number of layers. For example, the composition grading layer may be formed of four or more layers as illustrated in FIGS. 3 and 6.

FIG. 6 is a cross-sectional view illustrating an elemental composition in an example of the semiconductor light emitting device of FIG. 3.

Referring to FIG. 6, the first aluminum nitride of the first composition grading layer 3310 contacting the buffer layer 200 may include Al_{0.9}Ga_{0.1}N, and the second aluminum nitride of the first composition grading layer 3310 may include AlN. The composition of the first aluminum nitride of the first composition grading layer 3310 differs from the composition of the buffer layer 200, while the composition of the second aluminum nitride of the first composition grading layer 3310 is equal to the composition of the buffer layer 200 such that the effects of compositional changes may be minimized.

The first aluminum nitride of the second composition grading layer 3320 may include Al_{0.9}Ga_{0.1}N, and the second aluminum nitride of the second composition grading layer 3320 may include Al_{0.85}Ga_{0.15}N. When compared to the first composition grading layer 3310, the composition of the first aluminum nitride between the first composition grading layer 3310 and the second composition grading layer 3320 is unchanged and maintained such that the effects of compositional changes may be minimized, while a change in composition of the second aluminum nitride between the first composition grading layer 3310 and the second composition grading layer 3320 is made.

The first aluminum nitride of the third composition grading layer 3330 may include Al_{0.7}Ga_{0.3}N, and the second aluminum nitride of the third composition grading layer 3330 may include Al_{0.85}Ga_{0.15}N. When compared to the second composition grading layer 3320, the composition of the second aluminum nitride of the third composition grading layer 3330 is equal to the composition of the second aluminum nitride of the second composition grading layer 3320, while a change in composition of the first aluminum nitride between the second composition grading layer 3320 and the third composition grading layer 3330 is made.

After a change in composition of the second aluminum nitride is made between the first composition grading layer 3310 and the second composition grading layer 3320, a change in composition of the first aluminum nitride may be made between the second composition grading layer 3320 and the third composition grading layer 3330, on an alternating basis.

The first aluminum nitride of the fourth composition grading layer 3340 may include Al_{0.7}Ga_{0.3}N, and the second aluminum nitride of the fourth composition grading layer 3340 may include Al_{0.65}Ga_{0.35}N. When compared to the third composition grading layer 3330, the composition of the first aluminum nitride between the third composition grading layer 3330 and the fourth composition grading layer 3340 is unchanged and maintained, while a change in composition of the second aluminum nitride between the third composition grading layer 3330 and the fourth composition grading layer 3340 is made.

After a change in composition of the first aluminum nitride is made between the second composition grading layer 3320 and the third composition grading layer 3330, a change in composition of the second aluminum nitride may be made between the third composition grading layer 3330 and the fourth composition grading layer 3340, on an alternating basis.

The first aluminum nitride of the fifth composition grading layer 3350 may include Al_{0.6}Ga_{0.4}N, and the second aluminum nitride of the fifth composition grading layer 3350 may include Al_{0.65}Ga_{0.35}N. When compared to the fourth composition grading layer 3340, the composition of the second aluminum nitride between the fourth composition grading layer 3340 and the fifth composition grading layer 3350 is unchanged and maintained, while a change in composition of the first aluminum nitride between the fourth composition grading layer 3340 and the fifth composition grading layer 3350 is made.

After a change in the composition of the second aluminum nitride is made between the third composition grading layer 3330 and the fourth composition grading layer 3340, a change in the composition of the first aluminum nitride may be made between the fourth composition grading layer 3340 and the fifth composition grading layer 3350, on an alternating basis. Also, the composition grading layer 300 may include layers in which a gradual compositional change occurs in one of the first and second aluminum nitride while no compositional change is made in the other of the first and second aluminum nitride.

The composition of the first aluminum nitride of the fifth composition grading layer 3350 contacting the capping layer 400 may be equal to the composition of the capping layer 400 to minimize the effects of the compositional changes between the composition grading layer 300 and the capping layer 400.

When the composition grading layer 300 is formed of n layer, each of the first composition grading layer through the n^{th} composition grading layer may include at least two pairs of layers, for example, three pairs of layers, five pairs of layers, seven pairs of layers, ten pairs of layers, and the like, independently, however, the present inventive concept is not limited to a specific number of pairs of layers.

According to exemplary embodiments of the present inventive concept, a semiconductor light emitting device may minimize the effects of a compositional change between stacked layers, and may reduce a threading dislocation and various defects caused by a lattice mismatch that may occur between each layer when stacking, using a composition grading layer implementing gradual compositional changes in an alternating manner.

Also, the semiconductor light emitting device may prevent an extreme transformation of energy bands at an interface, may ensure uniformity through growth of a high-quality semiconductor thin film on a wafer, and may improve an optical power and reliability of a semiconductor light emitting device.

Hereinafter, the present inventive concept will be described with reference to the following examples. However, it should be understood that the inventive concept is not limited to the illustrated examples.

### Example

As a Comparative Example, a structure may be formed by stacking an AlN buffer layer, a composition grading layer including ten pairs of Al_{0.8}Ga_{0.2}N 20 nanometer (nm)/AlN 20 nm, and an nAl_{0.55}Ga_{0.45}N cladding layer on a 4 inch sapphire substrate in a sequential order.

As an Example according to an embodiment of the present inventive concept, a structure may be formed by stacking an AlN buffer layer, a composition grading layer including ten pairs of Al_{0.8}Ga_{0.2}N 20 nm/AlN 20 nm, a composition grading layer including ten pairs of Al_{0.8}Ga_{0.2}N 20 nm/Al_{0.7}Ga_{0.3}N 20 nm, and a composition grading layer including ten pairs of Al_{0.6}Ga_{0.4}N 20 nm/Al_{0.7}Ga_{0.3}N 20 nm, an Al_{0.6}Ga_{0.4}N 20 nm capping layer, and an nAl_{0.55}Ga_{0.45}N cladding layer on a 4 inch sapphire substrate in a sequential order.

Table 1 shows sheet resistivity (Rs) test data of the Comparative Example and the Example, and Table 2 shows X-ray diffraction (XRD) analysis data of the Comparative Example and the Example.

TABLE 1

| | | | | Standard | Sample | |
|---|---|---|---|---|---|---|
| | Aver- | Maxi- | Mini- | devia- | spread | Uniformity |
| Rs (2 μm) | age | mum | mum | tion | (%) | of wafer (%) |
| Comparative | 274.4 | 487.4 | 98.4 | 137.1 | 141.73 | 49.97 |
| Example | | | | | | |
| Example | 119.7 | 130.7 | 113.8 | 14.14 | 6.3 | 5.23 |

TABLE 2

| XRD | AlN 002 | AlGaN 002 | AlGaN 102 |
|---|---|---|---|
| Comparative Example | 377 | 442 | 886 |
| Example | 246 | 362 | 750 |

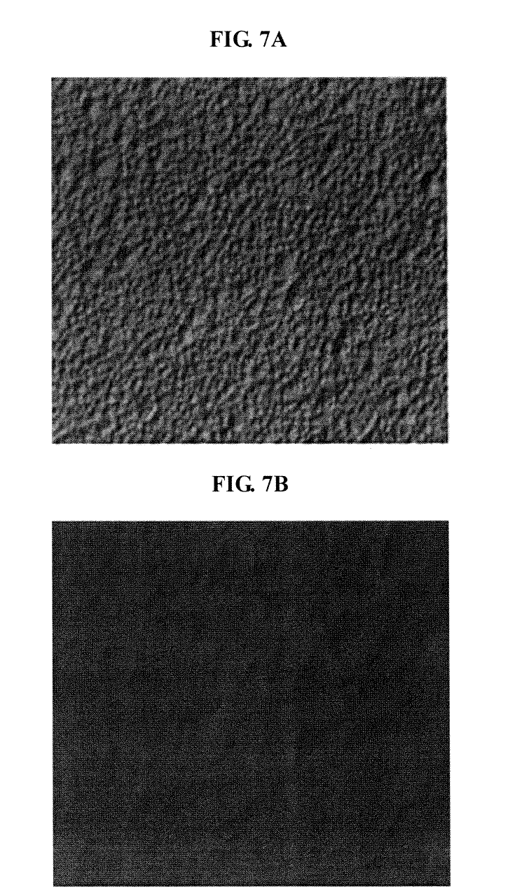

FIG. 7A is a photographic image of a surface of a center of a semiconductor light emitting device as a Comparative Example, and 7B is a photographic image of a surface of a center of a semiconductor light emitting device according to an exemplary embodiment of the present inventive concept.

As shown in FIG. 7B, it is found that the semiconductor light emitting device according to an exemplary embodiment of the present inventive concept has an improvement in terms of uniformity of a semiconductor material stacked on a wafer.

As a consequence of applying enhanced SLs (Super Lattice), improvements in terms of Rs, crystallinity, and uniformity may be obtained. This may result from surface energy control through filtering of dislocation caused by a lattice mismatch between layers and through strain adjustment.

A few exemplary embodiments of the present inventive concept have been shown and described. Nevertheless, it should be understood that various modifications may be made. For example, suitable results may be achieved if the described techniques are performed in a different order and/or if components in a described system, architecture, device, or circuit are combined in a different manner and/or replaced or supplemented by other components or their equivalents. It would be appreciated by those skilled in the art that changes may be made to these exemplary embodiments without departing from the principles and spirit of the invention, the scope of which is defined by the appended claims and their equivalents.

What is claimed is:

1. A semiconductor light emitting device, comprising:
a substrate;
a buffer layer disposed on the substrate, the buffer layer comprising aluminum nitride;
a composition grading layer disposed on the buffer layer, the composition grading layer comprising first aluminum nitride and second aluminum nitride;
a capping layer disposed on the composition grading layer; and
a cladding layer disposed on the capping layer,
wherein a composition of the first aluminum nitride and a composition of the second aluminum nitride change gradually in an alternating manner.

2. The light emitting device of claim 1, wherein the composition grading layer comprises a first composition grading layer through an n^{th} composition grading layer on the buffer layer.

3. The light emitting device of claim 2, wherein a concentration of aluminum in first aluminum nitride and second aluminum nitride of the (n−1)^{th} composition grading layer is greater than or equal to a concentration of aluminum in first aluminum nitride and second aluminum nitride of the n^{th} composition grading layer.

4. The light emitting device of claim 2, wherein a concentration of gallium in first aluminum nitride and second aluminum nitride of the (n−1)^{th} composition grading layer is less than or equal to a concentration of gallium in first aluminum nitride and second aluminum nitride of the n^{th} composition grading layer.

5. The light emitting device of claim 1, wherein a composition of the buffer layer is equal to a composition of second aluminum nitride of a lowermost layer of the composition grading layer.

6. The light emitting device of claim 1, wherein a composition of the capping layer is equal to a composition of first aluminum nitride of a topmost layer of the composition grading layer.

7. The light emitting device of claim 1, wherein each of the first aluminum nitride and the second aluminum nitride of the composition grading layer comprises aluminum gallium nitride (AlₓGa₁₋ₓN), independently, where 0≦x≦1.

8. The light emitting device of claim 1, wherein the cladding layer comprises AlₓGa₁₋ₓN, where 0.50≦x≦0.60.

9. The light emitting device of claim 2, wherein each of the first composition grading layer through the n^{th} composition grading layer includes at least two pairs of layers, independently.

10. A semiconductor light emitting device, comprising:
a substrate;
a buffer layer disposed on the substrate, the buffer layer comprising aluminum nitride;
a composition grading layer disposed on the buffer layer, the composition grading layer comprising first aluminum nitride and second aluminum nitride;
a capping layer disposed on the composition grading layer; and
a cladding layer disposed on the capping layer,
wherein the composition grading layer includes layers in which a gradual compositional change occurs in one of the first aluminum nitride and the second aluminum nitride while no compositional change is made in the other of the first aluminum nitride and the second aluminum nitride.

11. The light emitting device of claim 1, wherein a composition of the first aluminum nitride and a composition of the second aluminum nitride change gradually in an alternating manner.
